(19) United States
(12) Patent Application Publication
(10) Pub. No.: US 2018/0188335 A1
(43) Pub. Date: Jul. 5, 2018

(54) Magnetic Field Analysis Calculation Method, Magnetic Circuit Calculation Model Program Using Magnetic Field Analysis Calculation Method, and Recording Medium with Said Program

(71) Applicant: Hitachi, Ltd., Chiyoda-ku, Tokyo (JP)

(72) Inventors: Kazutami TAGO, Tokyo (JP); Kenji MIYATA, Tokyo (JP); Tomohito NAKANO, Tokyo (JP)

(21) Appl. No.: 15/741,901

(22) PCT Filed: Jul. 24, 2015
(86) PCT No.: PCT/JP2015/071052

§ 371 Date: Jan. 4, 2018

(51) Int. Cl. G01R 33/02; G01R 33/12; G01R 33/00; G06F 17/50; G01N 27/72

(52) U.S. Cl. CPC G01R 33/02; G01R 33/1215; G06F 2217/16; G06F 17/5018; G01N 27/72; G01R 33/0064

(57) ABSTRACT

In a magnetic field analysis calculation, there is a need to consider a characteristic that a magnetic field and a flux density face in different directions from each other by a stress in a magnetic material. Therefore, a measured value of a magnetic characteristic on a condition that the magnetic field, the magnetic flux density, and a mechanical stress are parallel is used. In a method and a device for magnetic field analysis calculation, a stress magnetic anisotropy is calculated using a relation between a magnetostriction of the magnetic material, the magnetic flux density, and the stress and a relation between a magnetization curve of the magnetic material, the magnetic flux density, and the stress which are measured on a condition that the magnetic field and the stress in the magnetic material are parallel.

### TECHNICAL FIELD

The invention relates to a magnetic field analysis calculation method, a magnetic circuit calculation model program using the magnetic field analysis calculation method, and a recording medium with the program.

### BACKGROUND ART

In a permanent magnet rotary machine, a torque called a cogging torque varies due to a mutual interaction between a permanent magnet and a stator core. In addition, a loss called an iron loss occurs in a core at the time of rotation. The cogging torque and the iron loss are evaluated by analyzing and calculating the magnetic field except a test after the rotary machine is manufactured.

On the other hand, when the core is manufactured, generally an electromagnetic steel sheet is molded by punching, and the stator is held in the case by generating pressure between the case and the stator. In a small motor for vehicles used in an electric power steering device, the cogging torque and the iron loss are influenced by the manufacturing method of the core. Therefore, there is a need of a magnetic field analysis calculation method which is able to perform evaluation in consideration of the influence of the manufacturing method. In the related art, the magnetic field is analyzed and calculated using a model of the magnetic characteristic in which the magnetic field is isotropically degraded by a mechanical strain and the stress caused at the time of manufacturing (NPL 1).

In the model of the magnetic characteristic, a measured value of the magnetic characteristic is used. The measured value of the magnetic field on a condition that the magnetic field, a magnetic flux density, and a mechanical stress are parallel is used. The reason why the condition is restricted to be parallel is because a measurement accuracy is not guaranteed from a restriction of a measurement device configuration. In practice, the magnetic field, the magnetic flux density, and the mechanical stress may be arranged in different directions from each other such that these components are not parallel but the magnetization is easily arranged in a direction of a tensile stress rather than a compression stress. Therefore, there is a request about an analysis calculation of the magnetic field in which the characteristic that the magnetic field and the magnetic flux density are arranged in different direction due to the stress (that is, a stress magnetic anisotropy) is able to be considered. In the related art, there is performed an attempt to combining degradation and improvement of the magnetic field in each direction of the principal stresses as independent components (NPL 2), but there are errors in angle and the magnetic field as disclosed in NPL 3. These errors are caused because it fails to consider a relation that the magnetic field in each direction of the principal stresses and the magnetic flux density are not independent but related to each other. In addition, there is an attempt to use a mechanic stress component in a magnetic field direction (NPL 4), but an angle between the magnetic field and the magnetic flux density is not calculated. In addition, there is also an attempt to calculate the magnetic field using a measurement result obtained on a condition that the magnetic field, the magnetic flux density, and the mechanical stress are not parallel (NPL 5), but there are problems in verification of the measurement accuracy, and in an increase of workload of measuring and modeling, and this attempt is not an actual solution.

### CITATION LIST

### Non-Patent Literature

NPL 1: “Motor Design Technologies Considering Deteriorated Magnetic Properties in Magnetic Core Due to Stamping” Shinichi Yamaguchi, Akihiro Daikoku, Yoshihiro Tani, Toshinori Tanaka, and Chiyo Fujino, Mitsubishi Electric Technical Report, 85, No. 7, pp 35-38 (2011), P413
NPL 2: “Cogging Torque Calculation Considering Distribution of Principal Stress of Stator Core in Permanent Magnet Motors” Masatsugu Nakano, Akihiro Daikoku, Shinichi Yamaguchi, Yoshihiro Tani, Hideaki Arita, Yukari Toide, Takashi Yoshioka, and Chiyo Fujino, The papers of Technical Meeting on Static Apparatus and Rotating Machinery, IEE Japan, SA-04-16, RA-04-16, (2004) p 13.
NPL 3: “An Improved Numerical Analysis of Flux Distributions in Anisotropic Materials” T. Nakata, K. Fujiwara, N. Takahashi, M. Nakano, and N. Okamoto, EEE TRANSACTIONS ON MAGNETICS, VOL. 30, NO. 5, SEPTEMBER 1994, p 3395.
NPL 4: “Studies on the Combined Stress and Electromagnetic Field Analysis of Interior Permanent Magnet Motors for Wide Speed Range Applications” Katsumi Yamazaki, and Hidetade Takeuchi, The papers of Technical Meeting on Static Apparatus and Rotating Machinery, IEE Japan, SA-13-84, RA-13-98, (2013) p 51.
NPL 5: “Vector Magnetic Characteristic Analysis of a PM Motor Considering Residual Stress Distribution With Complex-Approximated Material Modeling” Shingo Zeze, Yuichiro Kai, Takashi Todaka, and Masato Enokizono, IEEE TRANSACTIONS ON MAGNETICS, VOL. 48, NO. 11, NOVEMBER 2012, p 3352.

### SUMMARY OF INVENTION

### Technical Problem

The invention has been made in view of the above background, and an object of the invention is to use, in magnetic field analysis calculation, a measured value of a magnetic characteristic on a condition that the magnetic field, the magnetic flux density, and the mechanical stress are parallel in order to consider a characteristic (stress magnetic anisotropy) in which a magnetic field and a magnetic flux density are arranged to different directions due to a stress in a magnetic material.

### Solution to Problem

According to the invention to achieve the above object, a stress magnetic anisotropy is calculated using a relation between a magnetostriction of the magnetic material, a magnetic flux density, and a stress and a relation between a magnetization curve of the magnetic material, the magnetic flux density, and the stress which are measured on a condition that the magnetic field and the stress applied to the magnetic material are parallel.

### Advantageous Effects of Invention

According to the invention, it is possible to efficiently analyze and calculate a phenomenon that a magnetic field in a permanent magnet rotary machine is inclined by a stress magnetic anisotropy. In addition, it is possible to analyze and calculate a cogging torque and an iron loss with accuracy and efficiency.

### BRIEF DESCRIPTION OF DRAWINGS

FIG. 1 is a diagram illustrating a configuration of an analysis calculation system according to the invention.

FIG. 2 is a diagram illustrating a flow of a magnetic field calculation according to the invention (first embodiment).

FIG. 3 is a diagram for describing a distribution of magnetic flux lines which is calculated on a condition of no stress.

FIG. 4 is a diagram for describing a distribution of magnetic flux lines which is calculated in an example according to this embodiment.

FIG. 5 is a diagram for describing a cogging torque which is calculated in an example according to this embodiment.

### DESCRIPTION OF EMBODIMENTS

Next, a mode (referred to as “embodiment”) for carrying out the invention will be described in detail with reference to the drawings. Further, the same components in the respective drawings will be attached with the same symbol, and the description will be omitted.

In a small motor for vehicles which is used in an electric power steering device, a nonoriented electromagnetic steel sheet is rotated and stacked to produce a core. Therefore, the description in the following will be given using an example where a core is a polycrystalline steel sheet having an isotropic magnetic characteristic is stacked.

In this case, as energy affecting on a direction of magnetization in a magnetic material, there are crystal anisotropic energy, magnetostatic energy, magnetoelastic energy, and energy caused by a magnetic domain wall. Since a two-dimensional characteristic of a polycrystalline steel sheet which has an isotropic magnetic characteristic will be exemplified, the description will be given using the magnetoelastic energy and the magnetostatic energy in the following.

When there are a mechanical stress and an external magnetic field in the magnetic material, the direction of magnetization of the magnetic material is determined as a magnetization direction in which a sum of the magnetoelastic energy and the magnetostatic energy is minimized.

Since a distortion caused by the mechanical stress may be a value close to 10⁻³, elastic energy E_{σ}=−λ_{θ}σₛ caused by a mechanical stress σₛ and a magnetostriction in a direction of the stress is dominant in the magnetoelastic energy. Herein, λ_{θ} is a magnetostriction in a direction of a mechanical vertical stress when there is magnetization having an angle to the magnetic vertical stress.

$${λ}_{θ} = \frac{3}{2} λ ( {cos}^{2} ( {θ}_{M σ} ) - \frac{1}{3} ) \qquad [ Expression 1 ]$$

Herein, θ_{Mσ} represents an angle formed between the magnetization and the direction of stress. In addition, λ represents a magnetostriction in the magnetization direction, and satisfies λ_{θ}=λ when θ=0. In addition, a three-dimensional magnetoelastic energy is obtained by adding principal stresses as follows.

$${E}_{σ} = - \frac{3}{2} λ ( {σ}_{1} {α}_{1}^{2} + {σ}_{2} {α}_{2}^{2} + {σ}_{3} {α}_{3}^{2} - \frac{{σ}_{1} + {σ}_{2} + {σ}_{3}}{3} ) \qquad [ Expression 2 ]$$

Herein, σ_{I} is a principal stress. In addition, αᵢ is a direction cosine of magnetization in a coordination system of the principal stresses. Herein, as a specific example, when σ₁≠0, σ₂=σ₃=0, and M//B//σ₁ are satisfied, (3/2) λ (σ₁²−⅓)=λ=λ (B, σ₁) is satisfied, which corresponds to a relation of a magnetostriction, a magnetic flux density, and a stress which are measured on a condition that the magnetic field and the stress is parallel. A dependence of λ onto B and σ in a case where the directions of the principal stress and B is normal is set to satisfy the above specific example. For example, when λ=λ (B, σM) and σM=(3/2) (σ₁σ₁²+σ2σ₂²+σ3σ₃²−(σ₁+α2+α3)/3 are satisfied, σM is an equivalent stress in the magnetization direction and establishes the above specific example. In addition, when a stacked magnetic steel sheet is used and the principal stress in a third direction is assumed as “0”, the following two-dimensional expression is obtained.

$$\begin{matrix}{E}_{σ} = - \frac{3}{2} λ ( {σ}_{1} {α}_{1}^{2} + {σ}_{2} {α}_{2}^{2} - \frac{{σ}_{1} + {σ}_{2}}{3} ) \\ = - \frac{3}{4} λ ( ( {σ}_{1} - {σ}_{2} ) cos ( 2 {θ}_{M σ1} ) + \frac{{σ}_{1} + {σ}_{2}}{3} ) = - {λσ}_{M}\end{matrix} \\ {σ}_{M} = \frac{3}{4} ( {σ}_{1} - {σ}_{2} ) cos ( 2 {θ}_{M σ1} ) + \frac{{σ}_{1} + {σ}_{2}}{4} \qquad [ Expression 3 ]$$

A sum of the magnetoelastic energy and the magnetostatic energy becomes as follow.

E=−λσ_{M}−HM cos(θ_{HM}) [Expression 4]

Herein, θ_{HM} is an angle between the magnetic field and the magnetization. Herein, since a relative permeability of the electromagnetic steel sheet is extremely greater than “1”, the magnetization and the magnetic flux density are approximate and almost the same, and a formula to calculate an angle between the magnetic flux density and the magnetic field is derived.

$$\begin{matrix}E = - {λσ}_{B} - HB cos ( {θ}_{HB} ) \\ = - {λσ}_{B} - \frac{{μ}_{0} {μ}_{γ}^{0} {H}^{2}}{f} cos ( {θ}_{H σ1} - {θ}_{B σ1} )\end{matrix} \\ {σ}_{B} = \frac{3}{4} ( {σ}_{1} - {σ}_{2} ) cos ( 2 {θ}_{B σ1} ) + \frac{{σ}_{1} + {σ}_{2}}{4} \qquad [ Expression 5 ]$$

Herein, θ_{Bσ1} is an angle between the magnetic flux density and a first principal stress direction. In addition, λ is a magnetostriction in a direction of the magnetic flux density, and depends on a mechanical stress and a magnetic flux density. In addition, μ₀ is a permeability of the air, μᵣ⁰ is a relative permeability of a virgin electromagnetic steel sheet which is not yet affected by rotary machine processing, and f is a degradation degree of a magnetization curve caused by the rotary machine processing. Expression 6 shows a relational expression.

$$f = \frac{H ( B , σ )}{H ( B , 0 )} \\ H = H ( B , σ ) \\ B = {μ}_{0} {μ}_{γ}^{0} H ( B , 0 ) \qquad [ Expression 6 ]$$

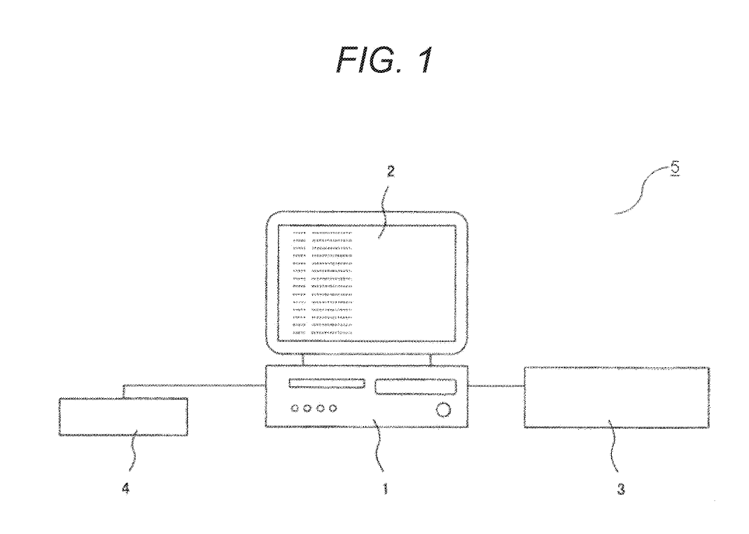

Herein, since λ(B, σ_{//}) can be measured on a condition that the stress, the magnetic field, and the magnetic flux density are parallel, the measured value is used as λ=λ (B, σ_{B}). As an example of a measured value, a measurement example of a nonoriented electromagnetic steel sheet is disclosed in “Technical Report of the Institute of Electrical Engineers of Japan, “High-degree application technique of electromagnetic analysis” (2014-9), vol. 1317, p 60, FIG. 1.125”, in which the horizontal axis represents the magnetic flux density, and the vertical axis represents the magnetostriction. The example shows that the magnetostriction is increased as the magnetic flux density is increased. The magnetostriction occurs positively in compression stress, but becomes negatively in a tensile stress. These changes vary depending on a type of the electromagnetic steel sheet. Therefore, it is desirable to use the relation between the measured magnetostriction, the magnetic flux density, and the stress.

Herein, a measured value f(B, σ_{//}) of the magnetization curve or the degradation degree can be obtained on a condition that the stress, the magnetic field, and the magnetic flux density are parallel. Therefore, the measured value is used as f=f(B, σH) using the equivalent stress in a magnetic field direction.

$${σ}_{H} = \frac{3}{4} ( {σ}_{1} - {σ}_{2} ) cos ( 2 {θ}_{H σ1} ) + \frac{{σ}_{1} + {σ}_{2}}{4} \\ f ( B , {σ}_{H} ) = \frac{H ( B , {σ}_{H} )}{H ( B , 0 )} \\ H = H ( B , {σ}_{H} ) \qquad [ Expression 7 ]$$

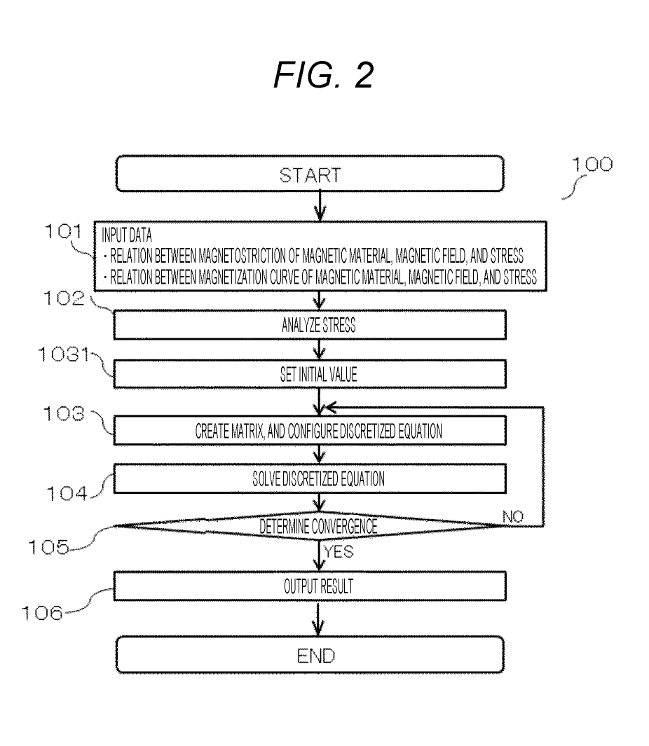

Expression 7 shows a magnetic field which depends on the magnetic flux density, the stress, and an angle of the magnetic field. An example of the magnetization curve on a condition that the stress and the magnetic field are parallel is disclosed in “Technical Report of the Institute of Electrical Engineers of Japan, “High-accuracy modeling technique of electromagnetic analysis of rotary machines” (2006-2), vol. 1044, p 27, FIG. 2.66(a)”, in which the vertical axis represents the magnetic flux density, and the horizontal axis represents the magnetic field. The example shows that a value of the magnetic flux density in the same magnetic field is decreased as the compression stress is increased. These changes vary depending on a type of the electromagnetic steel sheet. Therefore, it is desirably to use a relation between the measured magnetization curve, the magnetic flux density, and the stress.

By the formulation as described above, an angle to minimize the energy of Expression 5 is obtained by the following expression.

$$0 = \frac{\partial E}{\partial {θ}_{B σ1}} = - \frac{3}{2} λ ( {σ}_{1} - {σ}_{2} ) sin ( 2 {θ}_{B σ1} ) + \frac{\partial λ}{\partial {θ}_{B σ1}} {σ}_{B} - \frac{{fB}^{2}}{{μ}_{0} {μ}_{γ}^{0}} sin ( {θ}_{H σ1} - {θ}_{B σ1} ) \qquad [ Expression 8 ]$$

Herein, when λ (B, σ_{//}) and f(B, σ_{//}) are fitted to the relational formula, λ (B, α_{B}) and f(B, σ_{H}) also come into the relational formula. Therefore, Expression 8 can be solved numerically, and an angle (anisotropic angle) formed between the magnetic field and the magnetic flux density can be obtained. With the use of the obtained anisotropic angle and Expression 8, a relational formula of the magnetic field, a permeability tensor, and a tensor partially differentiated by the magnetic flux density of the magnetic field with respect to the magnetic flux density can be obtained. In other words, it is possible to obtain a magnetic characteristic in consideration of a stress magnetic anisotropy.

As can be seen from the above description, in a case where the magnetic field in the magnetic material is analyzed, the relation λ (B, σ_{//}) between the magnetostriction of the magnetic material, the magnetic flux density, and the stress which are measured on a condition that the stress and the magnetic field are parallel and the relation H(B, σ_{//}) or f(B, σ_{//}) between the magnetization curve of the magnetic material, the magnetic flux density, and the stress are used as inputs to obtain a distribution of the stress, the principal stress, and the direction of the stress by structural calculation. Therefore, it is possible to calculate the magnetic characteristic in consideration of the stress magnetic anisotropy, and an analysis calculation of the magnetic field in the magnetic material can be performed by using the magnetic characteristic. In addition, in order to efficiently perform the magnetic field calculation of the magnetic material in consideration of the stress magnetic anisotropy, it is apparent that the relation λ (B, σ_{//}) between the magnetostriction of the magnetic material, the magnetic flux density, and the stress and the relation H(B, σ_{//}) or f(B, σ_{//}) between the magnetization curve of the magnetic material, the magnetic flux density, and the stress which are measured on a condition that the stress and the magnetic field are parallel are effectively used when the magnetic characteristic is calculated in consideration of the stress magnetic anisotropy.

Herein, there is a conventional technique (JP H8-249621 A (PTL 1), International publication WO 2011/114492 A (PTL 2), International publication WO 2014/03388 A (PTL 3)) called a micromagnetics in which a behavior of the magnetization in crystal grains is simulated. The conventional technique is suitable to calculate a hysteresis characteristic of the magnetic material having a simple structure in consideration of crystal anisotropic energy, magnetostatic energy, magnetoelastic energy, and energy caused by a magnetic domain wall. On the other hand, the technique is not suitable to analysis of a complex structure such as a rotary machine from the viewpoint of time and memory necessary for the calculation. In addition, since λ (B, σ_{//}) and H(B, σ_{//}) can be calculated from basic information such as crystal structure information and a magnetostriction constant, there is no need to use these value as inputs, which is different from the embodiment of the invention. λ(B, σ_{//}) and H(B, σ_{//}) obtained in the technique may be used in the embodiment of the invention, but the accuracy of the measured value is more reliable at current stage.

In addition, in the conventional technique, the magnetostriction may be calculated using the magnetic flux density and the magnetostriction constant obtained by the magnetic field calculation as disclosed in JP 2014-71689 A (PTL 4). However, in the embodiment of the invention, the magnetic flux density is calculated using λ(B, σ_{//}) and H(B, σ_{//}), and as a result λ(B, σ_{B}) is obtained which is different from the embodiment.

The inventors have developed a magnetic characteristic calculation program in which the stress magnetic anisotropy is considered using λ(B, σ_{//}) and H(B, σ_{//}) or f(B, σ_{//}) as inputs, and have developed a magnetic field calculation system in which the stress magnetic anisotropy is considered by combining a stress calculation program and a magnetic field calculation program.

Next, the description will be given about a unit which applies the calculation method of the magnetic characteristic taken the stress magnetic anisotropy into consideration to analysis calculation of an actual magnetic field.

### (Example of System Configuration)

FIG. 1 is a diagram illustrating an exemplary configuration of an analysis calculation system according to this embodiment.

An analysis calculation system 5 includes an analysis calculation device 1, a display device 2, an input device 3, and a storage device 4. The analysis calculation device 1 is provided with a central processing device such as a CPU (Central Processing Unit), and also includes an inner storage device such as a memory and a cache.

The display device 2 is a display screen such as an image processing device and a liquid crystal display. The input device 3 is a direct input device and a medium input device such as a keyboard and a mouse. The storage device 4 is a storage medium which collectively refers to a device medium such as a semiconductor storage medium and a hard disk.

A stress calculation program, a magnetic characteristic calculation program in which the stress magnetic anisotropy is taken into consideration, and an analysis calculation program of a magnetic field are stored in the storage device 4, receives a user's command from the input device 3 during operation, performs processing by the analysis calculation device 1, and shows the result in the display device 2.

### Specific Example

Hereinafter, the description will be given about a specific example of a model configuration which operates in the analysis calculation system 5.

### First Embodiment

FIG. 2 is a diagram illustrating a flow of the magnetic field calculation according to this embodiment.

A flow 100 of the magnetic field calculation includes a data input portion 101, a stress analysis portion 102, an initial value setting portion 1031, a configuration portion 103 of matrix creating and discretized equation, a solving portion 104 of discretized equation, a convergence determining portion 105, and a result output portion 106.

In the data input portion 101, a relation between the magnetostriction of the magnetic material, the magnetic flux density, and the stress and a relation between the magnetization curve of the magnetic material, the magnetic flux density, and the stress which are measured on a condition that the stress and the magnetic field are parallel are input from the input device 3 in a formation such as measurement numerical data and function parameter data. Alternatively, a data file previously input to the storage device 4 is used.

In the stress analysis portion 102, an inner stress of a core caused by pressure between a stator core and a case is calculated by the structural calculation, and a principal stress and the direction thereof are calculated. Alternatively, a data file previously calculated and input to the storage device 4 is used.

In the initial value setting portion 1031, an initial value of a solution of the discretized equation of the magnetic field is set. The configuration portion 103 of matrix creating and discretized equation uses a relation between the magnetostriction of the magnetic material, the magnetic flux density, and the stress which are input in the data input portion 101, a relation between the magnetization curve of the magnetic material, the magnetic flux density, and the stress, the stress distribution, the principal stress, and the direction thereof obtained in the stress analysis portion 102 to calculate the magnetic characteristic in which the stress magnetic anisotropy is taken into consideration, to create a matrix of the discretized equation of the magnetic field, and to configure the discretized equation.

In the solving portion 104 of discretized equation, a solution of the discretized equation obtained in the initial value setting portion 103 is calculated by a matrix solution. In the convergence determining portion 105, the solution obtained in the solving portion 104 of the discretized equation is compared with the initial solution or the solution obtained at the last time to determine whether the result converges. In a case where the result does not converge, the procedure returns to the initial value setting portion 103, and proceeds to the next step of the repeated calculation. In a case where the result converges, the repeated calculation ends, and the procedure proceeds to the result output portion 106. In the result output portion 106, the calculation result such as a distribution of the magnetic field is output. According to this embodiment, it is possible to perform an analysis calculation of the magnetic field in which the stress magnetic anisotropy is taken into consideration.

In the data input portion 101 according to this embodiment, the relation between the magnetostriction, the magnetic flux density, and the stress, the relation between the magnetization curve (or the degradation degree of the magnetization curve), the magnetic flux density, and the stress can be received as inputs in a table format of numerical values. In addition, a file of a table format containing numerical values, a delimiter character, and a new-line character, or a file containing repetition data may be received as inputs. In addition, in a case where the above relations are given as a function, parameters of the function may be received as inputs.

The calculation program of the stress according to this embodiment, the calculation program of the magnetic characteristic in which the stress magnetic anisotropy is taken into consideration, and the analysis calculation program of the magnetic field are stored in the storage device 4. A user's command is received by the input device 3 to perform the calculation, and the result is displayed in the display device 2.

A processing portion 100 and the respective portions 101 to 106 are realized when the analysis calculation program stored in a read only memory (ROM) or a hard disk is developed to a random access memory (RAM) and executed by the CPU. Further, the magnetic characteristic calculation program in which the stress magnetic anisotropy is taken into consideration is recorded in a so-called computer-readable recording medium (for example, a magnetic recording medium such as a hard disk, an optical recording medium such as a compact disk-read only memory (CD) and a digital versatile disk (DVD)).

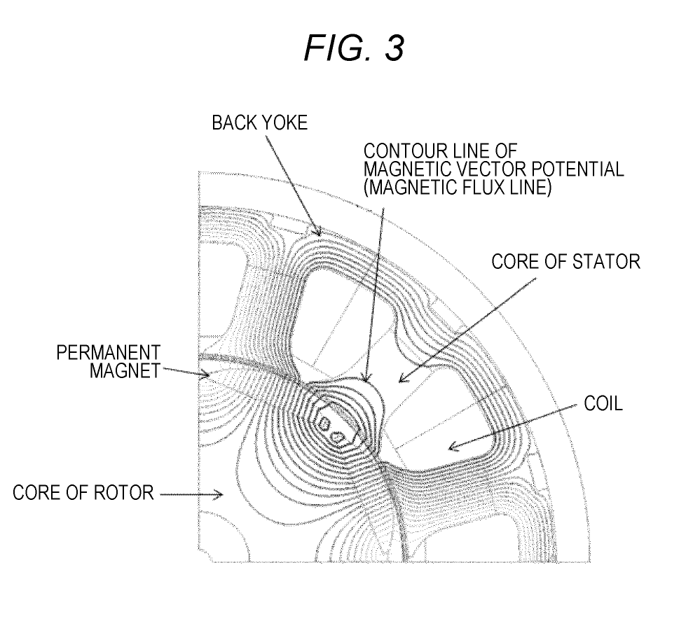

FIG. 3 is a diagram for describing a distribution of magnetic flux lines which are contour lines of magnetic vector potential calculated on a condition of no stress as a comparative example. The drawing illustrates a distribution of magnetic flux lines in a cross-sectional surface in a rotary surface of a permanent magnet rotary machine at the time of no power. Since the degradation in magnetic characteristic caused by the stress of a back yoke portion of the stator core is not taken into consideration, the magnetic flux lines flow smoothly in the back yoke portion.

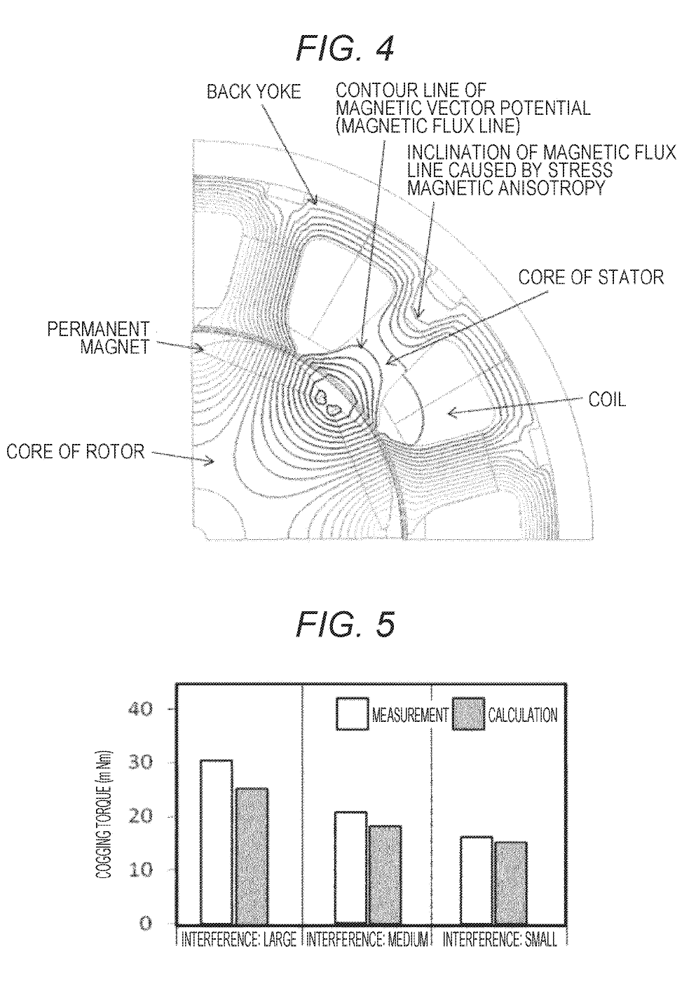

FIG. 4 is a diagram for describing a distribution of magnetic flux lines which are the contour lines of the magnetic vector potential calculated in the example according to this embodiment. Comparing to the distribution of the magnetic flux lines of FIG. 3, the magnetic flux lines are greatly bent toward a teeth side from the back yoke portion where the compression stress is strong, and the magnetic field in the permanent magnet rotary machine is inclined by the stress magnetic anisotropy.

FIG. 5 is a diagram for describing a cogging torque which is calculated in an example according to this embodiment. In measuring of the cogging torque, three stator cores having the structure illustrated in FIG. 3 of the same size are created by a wire cutting method, three aluminum cases of which the inner radius is smaller than the outer radius of the stator core are created, and three types of stator cores having stress are created by a shrink fitting method. Differences in radius are classified into large, middle, and small, respectively 118 μm, 55 μm, and 6 μm. As a rotor, the rotor having the structure illustrated in FIG. 3 is used commonly, torque at the time of rotating the rotor at a constant speed is measured, and the measured value of the cogging torque is obtained. In the calculation, the stress distribution generated in the stator core by the difference (interference) in radius is analyzed by the structural calculation, and the value of the principal stress and the direction thereof are calculated for every element of calculation meshes. Next, the magnetic characteristic in which the stress magnetic anisotropy is taken into consideration is calculated using the magnetostriction of FIG. 1.125 on page 60 of NPL 6 and the degradation degree of the magnetization curve of 50A290 electromagnetic steel sheet so as to calculate the distribution of the magnetic flux lines and the cogging torque. As illustrated in FIG. 5, even when the interference is large, the calculated value is matched within 20% of the measured value. According to the invention, it is determined that the cogging torque can be analyzed and calculated with accuracy and efficiency.

As described above, according to the invention, it is possible to calculate the magnetic field of the magnetic material with accuracy and efficiency.

### REFERENCE SIGNS LIST

1 analysis calculation device
2 display device
3 input device
4 storage device
5 analysis calculation system
100 flow of a magnetic field calculation
101 data input portion
102 stress analysis portion
1031 initial value setting portion
103 configuration portion of matrix creating and discretized equation
104 solving portion of discretized equation
105 convergence determining portion
106 result output portion

1. A magnetic field analysis calculation method in which a stress magnetic anisotropy is calculated using, as inputs, a relation between a magnetostriction, a magnetic flux density, and a stress of a magnetic material and a relation between a magnetization curve, the magnetic flux density, and the stress of the magnetic material which are measured on a condition that the magnetic field and the stress in the magnetic material are parallel.

2. The magnetic field analysis calculation method according to claim 1,
wherein the relation between the magnetostriction of the magnetic material, the magnetic flux density, and the stress which are measured on the condition that the magnetic field and the stress in the magnetic material are parallel is used as the relation between the magnetostriction, the magnetic flux density, and a stress in a direction of the magnetic flux density, and
wherein the relation between the magnetization curve of the magnetic material, the magnetic flux density, and the stress which are measured on the condition that the magnetic field and the stress in the magnetic material are parallel is used as the relation between the magnetization curve, the magnetic flux density, and the stress in the direction of the magnetic flux density.

3. The magnetic field analysis calculation method according to claim 1,
wherein the magnetic field is a magnetic field of a rotary machine, and a cogging torque is calculated using the magnetic field.

4. A program for calculating a stress magnetic anisotropy using, as inputs, a relation between a magnetostriction, a magnetic flux density, and a stress of a magnetic material and a relation between a magnetization curve, the magnetic flux density, and the stress of the magnetic material which are measured on a condition that the magnetic field and the stress in the magnetic material of a rotary machine are parallel.

5. A computer-readable recording medium wherein the program according to claim 4 is recorded.
